(19) United States
(12) Patent Application Publication
(10) Pub. No.: US 2016/0125960 A1
(43) Pub. Date: May 5, 2016

(54) SYSTEM AND METHOD FOR WRITE ABORT DETECTION

(71) Applicant: SanDisk Technologies Inc., Plano, TX (US)

(72) Inventors: Karin Inbar, Kfar Saba (IL); Irit Maor, Kfar Saba, IL (US); Mark Shlick, Kfar Saba (IL); Oded Nitzan, Kfar Saba (IL)

(73) Assignee: SanDisk Technologies Inc., Plano, TX (US)

(21) Appl. No.: 14/820,129

(22) Filed: Aug. 6, 2015

Related U.S. Application Data
(60) Provisional application No. 62/072,720, filed on Oct. 30, 2014.

(51) Int. Cl. G11C 29/52; G11C 29/12; G11C 29/50; G11C 29/44

(52) U.S. Cl. CPC G11C 29/52; G11C 29/44; G11C 29/1201; G11C 29/50004; G11C 2029/1202; G11C 2029/5004

(57) ABSTRACT

Systems, apparatuses, and methods are provided for write abort detection. A memory system may write data to one or more cells in a memory. An abrupt shutdown may interrupt the write, resulting in an uncertainty as to the state of the memory cells. In order to determine the state of the memory cells, after power-up, a first section of memory that includes the memory cells is analyzed, such as counting values of logic “0”s stored in the memory cells of the first section of memory. However, the values in the first section of memory may be subject to error, hindering the accuracy of write abort detection. In order to reduce or cancel the effect of the errors, a second section of memory (which may suffer from similar errors as the first section) is analyzed, such as by counting values of logic “0”s stored in the memory cells of the second section of memory. The differential value of the counts from the two sections is determined, thereby reducing or eliminating the effect of the errors, and then analyzed to determine the state of the first section of memory for write abort detection.

### REFERENCE TO RELATED APPLICATION

This application claims the benefit of U.S. Provisional Application No. 62/072,720, which is hereby incorporated by reference herein in its entirety.

### TECHNICAL FIELD

This application relates generally to managing data in a memory system. More specifically, this application relates to analyzing data in sections of memory to detect a write abort.

### BACKGROUND

A memory system, such as non-volatile flash memory system, may comprise a plurality of memory cells in which data may be stored. In operation, the memory controller of the memory system may program and/or erase the memory cells. Occasionally, the memory controller may experience an abrupt power shutdown during an ongoing write operation to the memory cells. The abrupt power shut down may generate an undesirable condition whereby the memory cells are programmed or erased to un-certain levels. More specifically, due to the abrupt power shutdown, the memory controller was unable to verify the program or erase of the memory cells.

At the next power-up, the memory controller and a host device may verify which blocks were programmed and/or erased properly, and which blocks were not and, in turn, should be marked as write abort blocks. For example, the memory controller may scan the memory blocks that were last written (according to stored metadata) and count the number of programmed bits (logic “0”s) in each flash memory unit (FMU) in a wordline (WL), which may be composed of multiple FMUs.

The memory controller then compares the count with multiple thresholds. In particular, in the event that the count is less than a first threshold (e.g., an erased threshold), the memory controller designates the FMU as an erased FMU. In the event that the count is greater than a second threshold (e.g., a programmed threshold), the memory controller designates the FMU as a programmed FMU. Finally, in the event that the count is between the first threshold and the second threshold, the memory controller designates the FMU as a suspected write abort FMU.

Blocks that include suspected write abort FMUs are designated as write abort blocks. In response to this designation, the memory controller will not access the designated blocks, either for a write or an erase. During the memory system's lifetime, the number of marked write abort blocks increases, thereby reducing the memory system's performance and increasing the likelihood of the memory system's failure.

### BRIEF SUMMARY

Systems and methods for determining a write abort in a memory system are disclosed. In one aspect, a memory system is disclosed. The memory system includes a differential generator module configured to generate a differential between an aspect in data values stored a first section in memory and the aspect in data values stored a second section in memory; a comparison module configured to compare the differential with a differential threshold; and a write abort module configured to determine, based on the comparison of the differential with the differential threshold, whether at least one of the first section or the second section is subject to a write abort.

In another aspect, a method for determining whether a write abort occurred when writing to a section of memory is disclosed. The method includes: reading a first part of the section of the memory in order to generate a first count; reading a second part of the memory in order to generate a second count; comparing the first count with the second count; and determining, based on the comparison of the first count with the second count, whether a write abort occurred at the first section of the memory.

Other features and advantages will become apparent upon review of the following drawings, detailed description and claims. Additionally, other embodiments are disclosed, and each of the embodiments can be used alone or together in combination. The embodiments will now be described with reference to the attached drawings.

### BRIEF DESCRIPTION OF THE DRAWINGS

The system may be better understood with reference to the following drawings and description. In the figures, like reference numerals designate corresponding parts throughout the different views.

FIG. 1A is a block diagram of a non-volatile memory system of an embodiment.

FIG. 1B is a block diagram illustrating an exemplary storage module of an embodiment.

FIG. 1C is a block diagram illustrating a hierarchical storage system of an embodiment.

FIG. 2A is a block diagram illustrating exemplary components of the controller of the non-volatile memory system illustrated in FIG. 1A according to an embodiment.

FIG. 2B is a block diagram illustrating exemplary components of the non-volatile memory of the non-volatile memory storage system illustrated in FIG. 1A according to an embodiment.

FIG. 2C is a block diagram illustrating exemplary components of the abort management module of the abort management module illustrated in FIG. 2A.

FIG. 3 is a circuit schematic diagram of a portion of a memory block.

FIG. 4 is a diagram illustrating an SLC block scan.

FIG. 5 is a first example of a flow diagram to determine whether a write abort has occurred.

FIG. 6A illustrates the different thresholds for logic “0”s count per FMU.

FIG. 6B illustrates the threshold for the differential in logic “0”s count per FMU in at least two different FMUs.

FIG. 7 is a second example of a flow diagram to determine whether a write abort has occurred.

### DETAILED DESCRIPTION

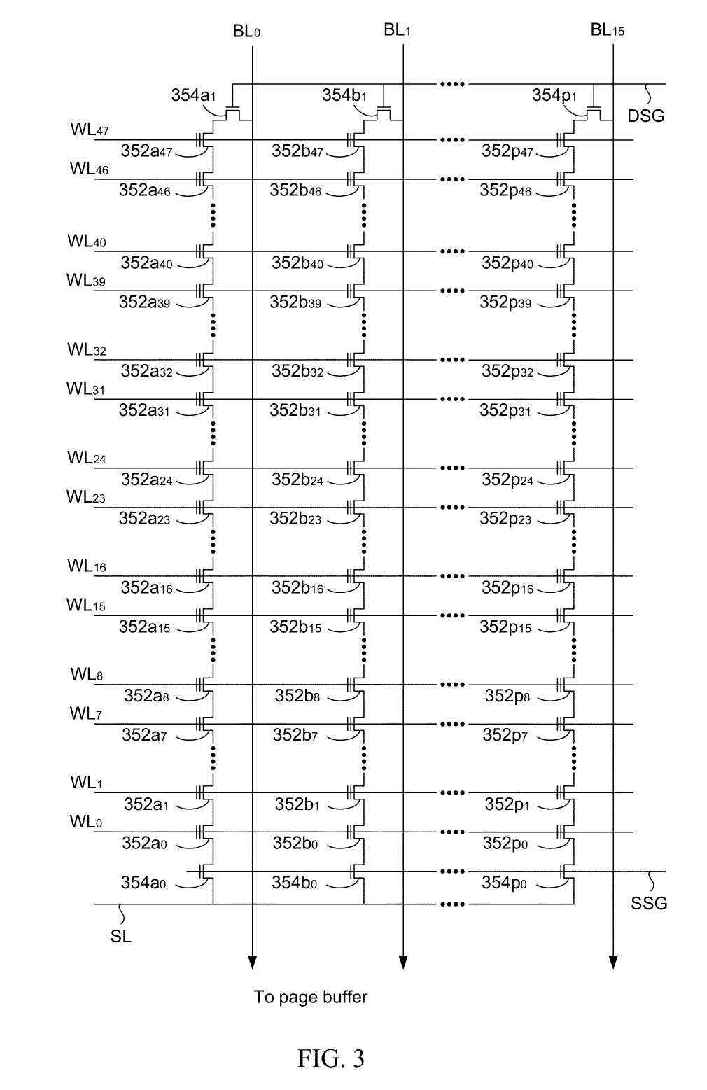

Prior to programming a section of a memory system, the section may be in a predetermined state. After which, part or all of the section of memory may be programmed. For example, in flash memory, a block is erased prior to programming in order to put the memory cells in the block to the logic “1” state. Thereafter, the memory cells in the block may be programmed. In one implementation, the block is composed of multiple pages, with each page being composed of the memory cells along a single wordline (WL), illustrated below in FIG. 3. In one embodiment, the wordlines may be composed of multiple flash memory units (FMUs), which is the unit of programming.

An abrupt power shutdown that occurs during programming may result in the memory cells being in an indeterminate state. For example, in flash memory, the memory cells that comprise the FMU may be in one of three states: (1) erased; (2) programmed; or (3) indeterminate state.

One may analyze the values stored in a part of the block, such as count the logic “0” in a part of the block (e.g., count the values stored in an FMU), and compare it to one or more thresholds in order to determine the state of the FMU. In the example of an erased FMU, the memory cells should be in the logic “1” state (i.e., few of the memory cells are in the “0” state). In this regard, the count of logic “0” in a respective FMU is compared to Threshold₁, which may be considered an erased threshold. If the count is less than Threshold₁, the respective FMU is designated as being erased. Conversely, in the example of a programmed FMU, fewer memory cells should be in the logic “1” state (i.e., more of the memory cells are in the “0” state). In this regard, the count of logic “0” in a respective FMU is compared to Threshold₂, which may be considered a programmed threshold. If the count is greater than Threshold₂, the respective FMU is designated as being programmed. Finally, if the count is between Threshold₁ and Threshold₂, the respective FMU is designated as being in the indeterminate state.

Simply comparing the count in the FMU to one or more thresholds may be unreliable. More specifically, variables within the memory system may result the values stored in the memory cells being unreliable. In turn, the count being based on the values stored in the memory cells may be unpredictable, resulting in the comparison of the count with the thresholds potentially generating erroneous results. As one example, the memory system may have one or more bad columns. As illustrated in FIG. 3, the columns program or erase cells. However, a fraction of the columns may be bad columns, which may prevent programming or erasing the memory cells connected to the bad columns. The existence of a different number of bad columns in a FMU may mislead the two thresholds write abort detection scheme described above. For example, if a block includes 33 bad columns, the cells that were supposed to be erased or programmed by the bad columns are not, potentially resulting in an erroneous count and, in turn, a potentially erroneous designation as a suspected write abort block. In this regard, in the event that the threshold has a value of 30 and given that the block has 33 bad columns (resulting in 33 logic “0”s being counted), the block will erroneously be designed with a write abort.

As another example, the memory system performance degrades with age. More specifically, flash performance may degrade due to large number of program/erase (P/E) cycles, resulting in charge loss from floating gates, erased tails, and the like. The degrading in performance results in an erroneous count, and in turn, a potentially erroneous designation as a suspected write abort block.

In one embodiment, the state (e.g., programmed, erased, or indeterminate) of a first section of memory is determined, and in turn, whether a write abort occurred when programming the first section of memory. In order to perform the determination, the first section of memory and a second section of memory are analyzed. The first and second sections may comprise any part of the memory, such as different FMUs, different wordlines, or the like.

The second section of memory may be selected based on at least one similar aspect to the first section of memory and/or based on a known or suspected state of the second section of memory. In one embodiment, the second section of memory may be selected to be from the same block (or other similar sub-part of the memory) as the first section of memory. In this regard, errors due to programming and/or erasing of the first section of memory may likewise occur in programming and/or erasing of the second section of memory, with the differential canceling (or reducing the effect of) the errors. In the instance of bad column errors, affecting programming of cells in the first section of memory, the second section of memory, which may experience the same or similar bad column errors, may be selected, thereby reducing the effect of the bad column errors. In another embodiment, the second section of memory may be selected based on a known or suspected state, such as known/suspected to be erased or known/suspected to be programmed. In this way, comparing the first section of memory with the known state of the second section of memory may more easily establish the state of the first section of memory.

Further, the analysis may comprise counting values stored in the memory cells in the respective section of memory, such as counting the logic “0”s or the logic “1”s in the FMU. The analysis of the first section of memory and the analysis of the second section of memory may be compared. For example, the count of the “0”s in the memory cells of the first section of memory may be compared with the count of the “0”s in the memory cells of the second section of memory. More specifically, the difference in the counts of the “0”s in the first and second sections of memory may be determined, as discussed in more detail below. Based on the comparison, the state of the first section of memory is determined. For example, the difference in the counts of the “0”s in the first and second FMUs may be compared to a difference threshold. If the difference is less than the threshold, the first FMU may be designated as truly erased.

In the context of write abort analysis, generating a differential between an aspect of data values stored in the first section of memory (e.g., the count of the logic “0”s in the first section of memory) and the aspect of data values stored in the second section of memory may result in a more reliable indicator whether a write abort has occurred. More specifically, the memory system may have errors that, in turn, result in common errors for data values stored in the first and second sections of memory. As one example, bad column errors will appear in all WLs of a respective block connected to the bad columns. Thus, if a first FMU in the respective block is being analyzed, a second FMU in the respective block may suffer from the same bad column errors. As another example, block age-related errors, such as due to a high number of P/E cycles, may affect the entire block in a similar manner. In this regard, the first FMU and the second FMU, both in the same respective block, may suffer from the same or similar block age-related errors. Because the differential of an aspect of the data values stored in the first and second sections of memory is generated, the common errors manifested in the data values may be reduced or eliminated, thereby rendering the differential as a more reliable indicator in determining whether a write abort has occurred. Thus, instead of only analyzing the at least one aspect alone (e.g., comparing the count of logic “0”s against a threshold), the differential between the aspects of the data values stored in the first and second sections of memory may result in a reduction in the noise due to common errors.

In one embodiment, both the aspect of the data values stored in the first section of memory and the differential of the aspect of the data values stored in the first section and the second section are analyzed to determine whether a write abort has occurred. For example, both the count of the logic “0”s in a first FMU is compared against multiple thresholds, and the differential of the count of the logic “0”s in the first FMU and the second FMU is compared against at least one threshold in order to determine whether a write abort has occurred, as discussed in more detail below. In an alternate embodiment, only the differential of the aspect of the data values stored in the first section and the second section is analyzed to determine whether a write abort has occurred.

Further, the second section of memory, used to generate the differential with the first section of memory, may be selected based on one or more criteria. In one embodiment, the second section of memory is selected such that it is in the same sub-part of the memory as the first section of memory. For example, the first section of memory may comprise a first FMU in a respective block. The second section of memory may comprise a second FMU in the same respective block. As the first and second FMUs are from the same block, common errors may be reduced, as discussed above. In another embodiment, the second section of memory may be selected based on a known or reasonable belief as to its state. For example, the second section of memory may comprise an FMU in the last WL of a block. The last WL of the block is the last to be programmed. Thus, the last WL is the most likely WL in the block to be in the totally erased state, and is a good baseline for a section of memory that is erased. Conversely, the second section of memory may comprise an FMU in the first WL of a block. The first WL of the block is the first to be programmed. Thus, the first WL is the most likely to be in the programmed or non-erased state, and is a good baseline for a section of memory that is programmed or non-erased.

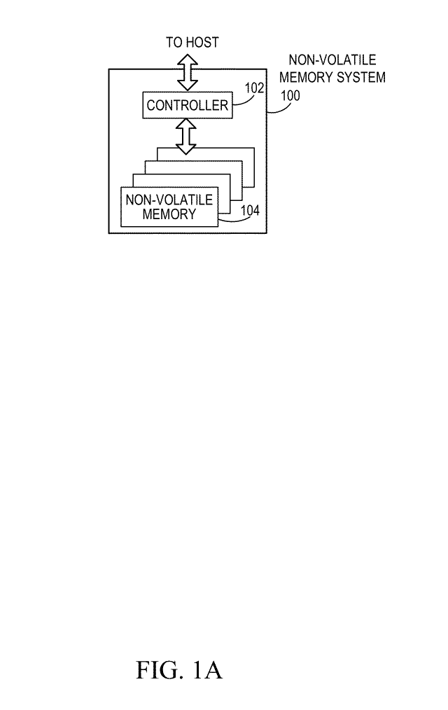

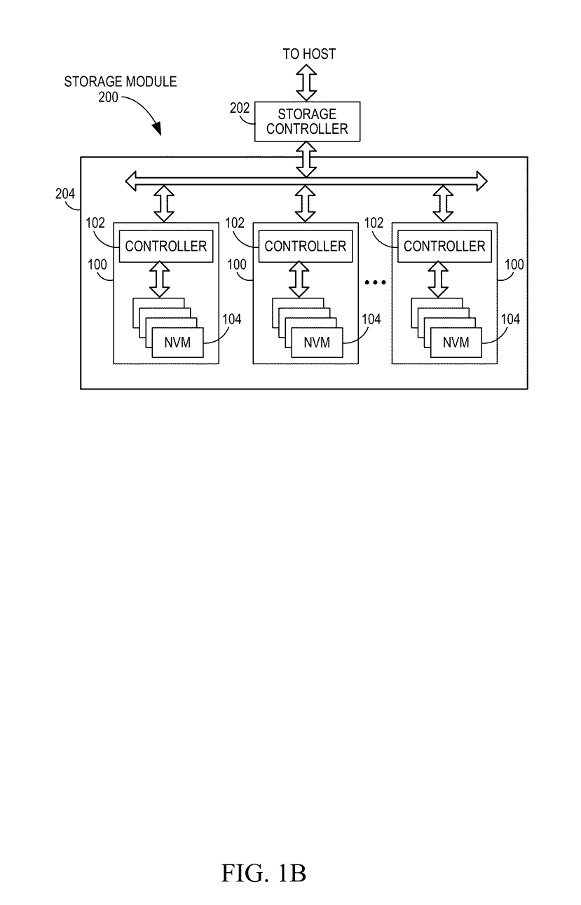

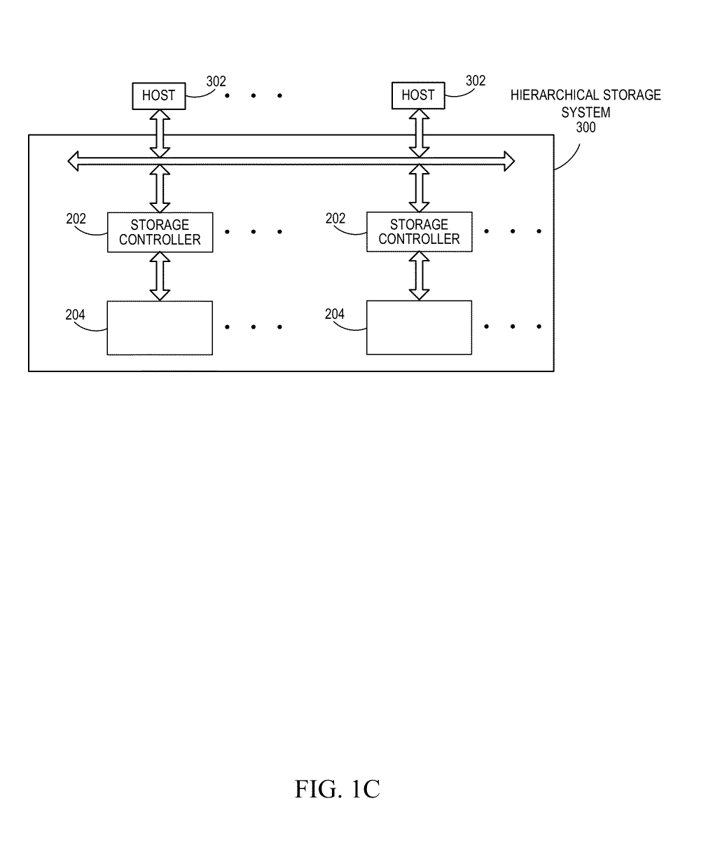

FIG. 1A is a block diagram illustrating a non-volatile memory system 100 according to an embodiment of the subject matter described herein. Referring to FIG. 1A, non-volatile memory system 100 includes a controller 102 and one or more non-volatile memory die 104. As used herein, the term die refers to the set of non-volatile memory cells, and associated circuitry for managing the physical operation of those non-volatile memory cells, that are formed on a single semiconductor substrate. Controller 102 interfaces with a host system and transmits command sequences for read, program, and erase operations to non-volatile memory die 104. Examples of host systems include, but are not limited to, a mobile phone, a tablet computer, a digital media player, a game device, a personal digital assistant (PDA), a mobile (e.g., notebook, laptop) personal computer (PC), or a book reader.

Controller 102 can take the form of a microprocessor or processor and a computer-readable medium that stores computer-readable program code (e.g., software or firmware) executable by the (micro)processor, logic gates, switches, an application specific integrated circuit (ASIC), a programmable logic controller, and an embedded microcontroller, for example. Controller 102 can be configured with hardware and/or software to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

Non-volatile memory die 104 may include any suitable non-volatile storage medium, including NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC), triple-level cells (TLC), or use other memory technologies, now known or later developed. Also, the memory cells can be arranged in a two-dimensional or three-dimensional fashion.

Thus, the memory may be a semiconductor memory device that includes volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory system can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements.

The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

The interface between controller 102 and non-volatile memory die 104 may be any suitable flash interface, such as Toggle Mode 200, 400, or 800. In one embodiment, memory system 100 may be a card based system, such as a secure digital (SD) or a micro secure digital (micro-SD) card. In an alternate embodiment, memory system 100 may be part of an embedded memory system.

Although in the example illustrated in FIG. 1A, memory system 100 (sometimes referred to herein as a storage module) includes a single channel between controller 102 and non-volatile memory die 104, the subject matter described herein is not limited to having a single memory channel. For example, in some NAND memory system architectures, 2, 4, 8 or more NAND channels may exist between the controller and the NAND memory device, depending on controller capabilities. In any of the embodiments described herein, more than a single channel may exist between the controller and the memory die, even if a single channel is shown in the drawings.

FIG. 1B illustrates a storage module 200 that includes plural non-volatile memory systems 100. As such, storage module 200 may include a storage controller 202 that interfaces with a host and with memory system 204, which includes a plurality of non-volatile memory systems 100. The interface between storage controller 202 and non-volatile memory systems 100 may be a bus interface, such as a serial advanced technology attachment (SATA) or peripheral component interface express (PCIe) interface. Storage system 200 illustrated in FIG. 1B, in one embodiment, may be a solid state drive (SSD), such as found in portable computing devices, such as laptop computers, tablet computers, and mobile phones.

FIG. 1C is a block diagram illustrating a hierarchical storage system according to an embodiment. Referring to FIG. 1C, a hierarchical storage system 300 includes a plurality of storage controllers 202, each of which control a respective memory system 204. Host systems 302 may access memories within the storage system via a bus interface. In one embodiment, the bus interface may be a serial attached SCSI (SAS) or fiber channel over Ethernet (FCoE) interface. In one embodiment, the system illustrated in FIG. 1C may be a rack mountable mass storage system that is accessible by multiple host computers, such as would be found in a data center or other location where mass storage is needed.

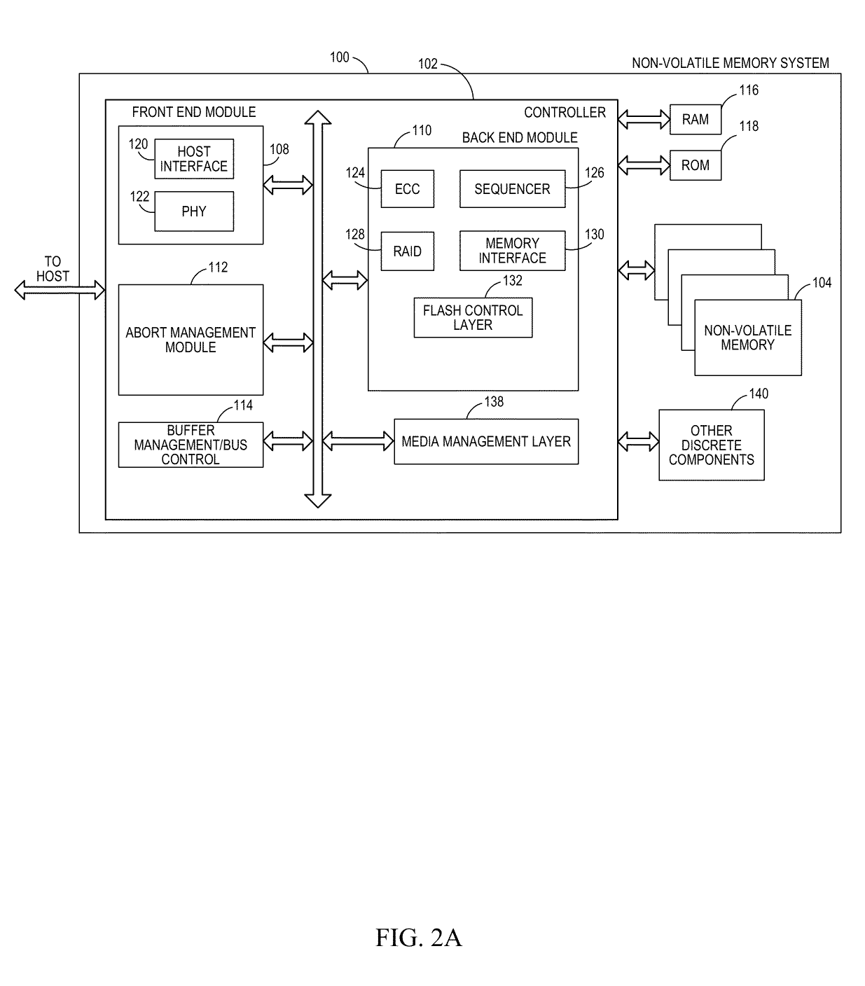

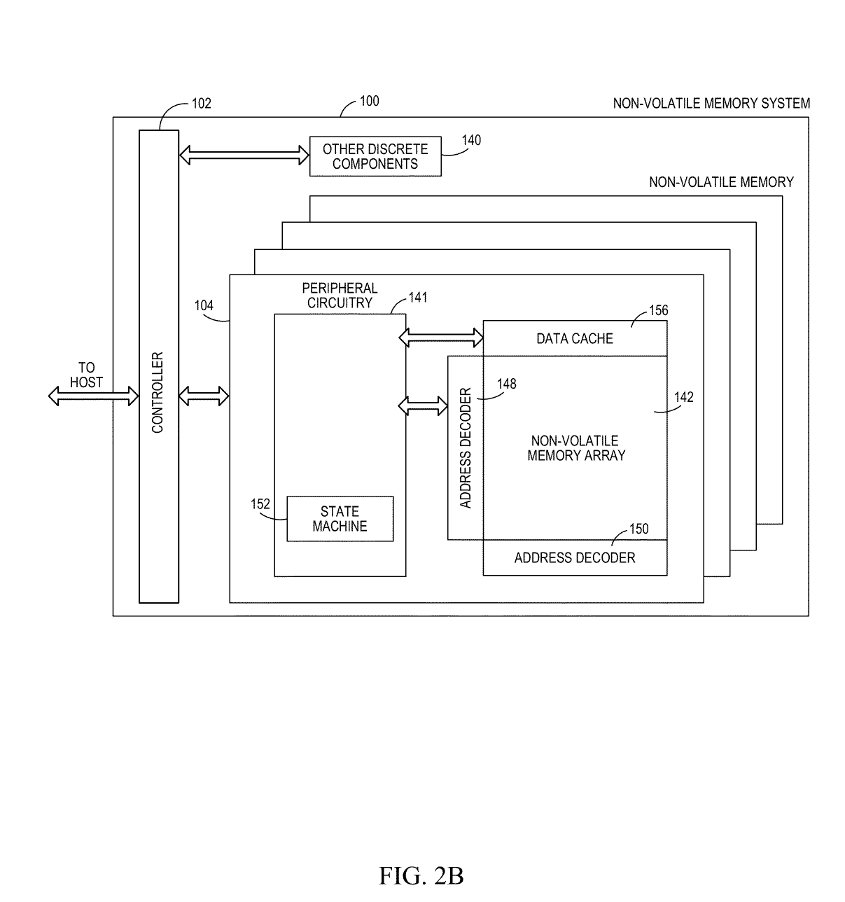

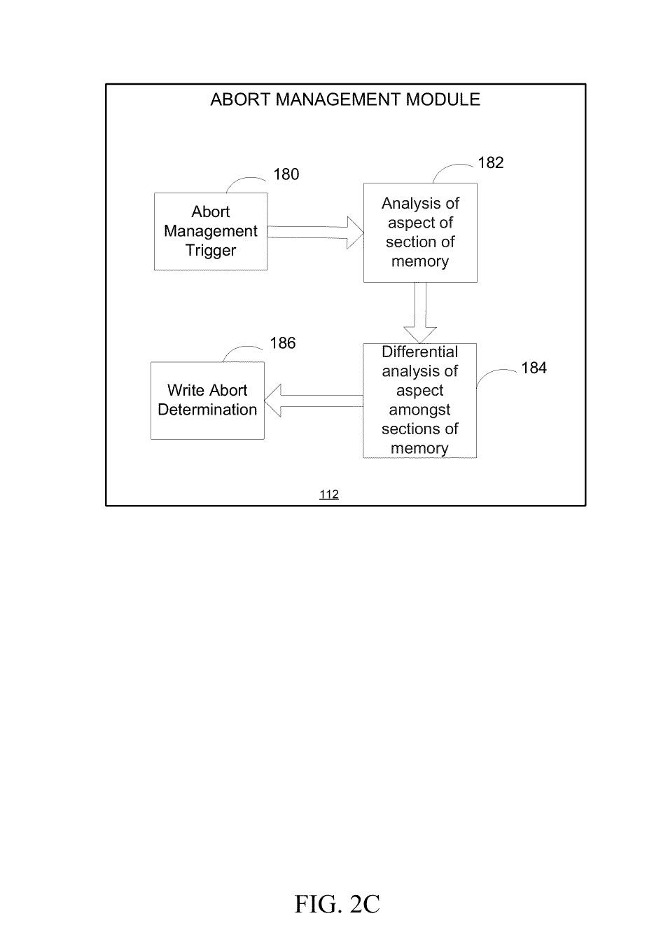

FIG. 2A is a block diagram illustrating exemplary components of controller 102 in more detail. Referring to FIG. 2A, controller 102 includes a front end module 108 that interfaces with a host, a back end module 110 that interfaces with the one or more non-volatile memory die 104, and various other modules that perform functions which will now be described in detail. In the illustrated example, these modules include a abort management module 112 that performs write abort analysis functions for controller 102. A buffer manager/bus controller 114 manages buffers in random access memory (RAM) 116 and controls the internal bus arbitration of controller 102. A read only memory (ROM) 118 stores system boot code. Although illustrated in FIG. 2A as located separately from the controller 102, in other embodiments one or both of the RAM 116 and ROM 118 may be located within the controller. In yet other embodiments, portions of RAM and ROM may be located both within the controller 102 and outside the controller. Front end module 108 includes a host interface 120 and a physical layer interface (PHY) 122 that provide the electrical interface with the host or next level memory controller.

Back end module 110 includes an error correction controller (ECC) engine 124 that performs encoding on the data bytes received from the host, and decoding and error correction on the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a dual data rate (DDR) interface, such as a Toggle Mode 200, 400, or 800 interface. A flash control layer 132 controls the overall operation of back end module 110.

Additional components of system 100 illustrated in FIG. 2A include media management layer 138, which performs wear leveling of memory cells of non-volatile memory die 104. System 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller 114 are optional components that are not necessary in the controller 102.

FIG. 2B is a block diagram illustrating exemplary components of non-volatile memory die 104 in more detail. Referring to FIG. 2B, non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including NAND flash memory cells and/or NOR flash memory cells in a two dimensional and/or three dimensional configuration. Peripheral circuitry 141 includes a state machine 152 that provides status information to controller 102. Non-volatile memory die 104 further includes a data cache 156 that caches data.

FIG. 2C is a block diagram illustrating exemplary components of the abort management module 112 illustrated in FIG. 2A. Abort management module 112 may include abort trigger management trigger 180, which may comprise the trigger to begin the abort management analysis upon power-up. As discussed above, at least one aspect, such as the count of the logic “0”s, may be analyzed with respect to a section of memory. More specifically, the aspect may be analyzed with respect to the section of memory alone, and/or differentially with respect to another section of memory. In this regard, in response to the trigger to the abort management analysis, analysis of aspect of section of memory 182 may analyze the aspect of the section of memory (such as compare the count of the logic “0”s) with one or more thresholds. Further, differential analysis of the aspect amongst different sections of memory 184 may differentially analyze the aspect of the section of memory with one or more thresholds. Based on the analysis from 182 and/or 184, write abort determination 186 may determine whether a write abort has occurred.

FIG. 3 is a circuit schematic diagram of a portion of a memory block. The portion shown in FIG. 3 includes a plurality of strings of forty-eight FGTs connected in series, including a first string of FGTs 352a₀ to 352a₄₇ and a second string of FGTs 352b₀ to 352b₄₇ extending to a sixteenth string of FGTs 352ₚ₀ to 352ₚ₄₇. A complete block may include many more strings than sixteen. In addition, numbers other than forty-eight FGTs per string and/or forty-eight wordlines may alternatively be used.

For the portion shown in FIG. 3, the first string is coupled to a first bitline BLₒ. The second string is coupled to a second bitline BL₁, and the sixteenth string is coupled to a sixteenth bitline BL₁₅. Additionally, the portion shown in FIG. 3 includes forty-eight wordlines WL₀ to WL₄₇ coupled to forty-eight pages of FGTs—wordline WL₀ is coupled to control gates of FGTs in a first page comprising FGT 352a₀, 352b₀, . . . , 352p₀; wordline WL₁ is coupled to control gates of FGTs in a second page comprising FGT 352a₁, 352b₁, . . . , 352p₁; and so on.

To perform a sense portion of a read or copy operation, a page of FGTs and a corresponding wordline may be selected, and current sensing of bitlines may be employed to determine whether a floating gate of a FGT in the selected page contains charge or not. Current flowing through a string may flow from a source line SL, through the string, to the bitline BL to which the string is coupled. The string may be coupled to the source line SL via a source select transistor and may be coupled to its associated bitline BL via a drain select transistor. For example, as shown in FIG. 3, the first string of FGTs 352a₀ to 352a₆₃ may be coupled to the source line SL via a source select transistor 354a₀ that is connected to the source line SL and a first end FGT 352a₀ of the first string. The other strings may be similarly coupled. Further, switching of the source select transistors 354a₀, 354b₀, . . . , 354p₀ may be controlled using a source select gate bias line SSG that supplies a source select gate bias voltage V_{SSG} to turn on an off the source select transistors 354a₀, 354b₀, . . . , 354p₀. Additionally, switching of the drain select transistors 354a₁, 354b₁, . . . , 354p₁ may be controlled using a drain select gate bias line DSG that supplies a drain select gate bias voltage V_{DSG} to turn on and off the drain select transistors 354a₁, 354b₁, . . . , 354p₁.

As discussed above, there may be errors in one or more of the bitlines. In this regard, an error in a respective bitline will affect respective cells in different wordlines similarly. For example, if BL₀ is faulty, transistor 352a₁₆ in wordline WL₁₆ and transistor 352a₄₇ in wordline WL₄₇ may be similarly affected. Thus, differential analysis of the values of the transistors in the different bitlines may reduce or cancel the affect due to bitline error, as discussed above. For example, the bad column resulting in errors in erasing and/or programming of WL₁₆ may likewise affect erasing and/or programming of WL₄₇. The differential of values stored in WL₁₆ and WL₄₇ may have the effect of canceling or reducing the effect of the bad columns.

In one instance, the last wordline in the block (such as WL₄₇) may be analyzed for write abort detection. In one embodiment, determination that the last wordline in the block may be subject to write abort detection may automatically result in designating the block as write abort. In an alternate embodiment, the values stored in the last wordline in the block may be compared with values stored in another section of the memory, such as values stored in the second-to-last wordline in the block. The comparison may comprise generating a differential value, as discussed above.

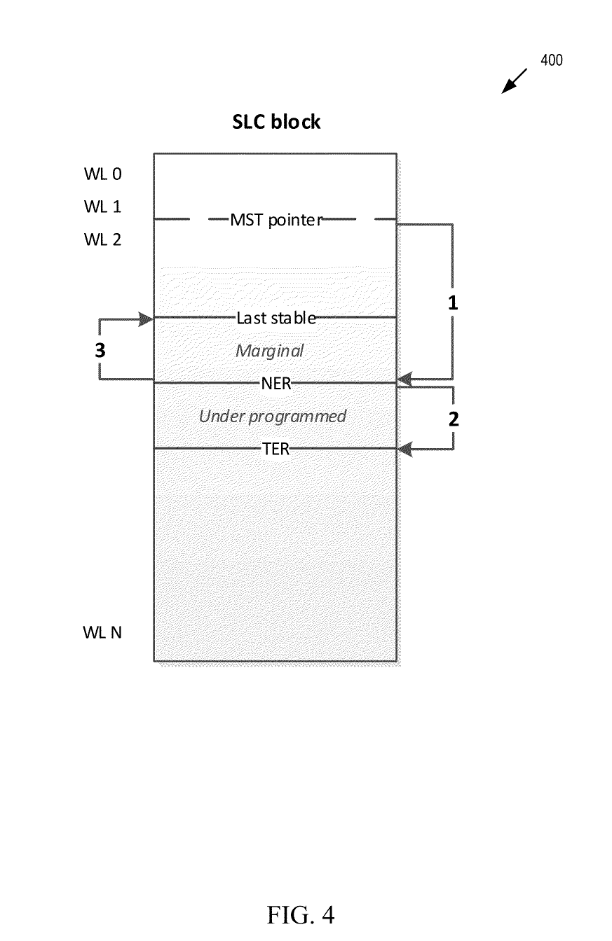

FIG. 4 is a diagram illustrating a scan of an SLC block 400. A Master Table (MST) Pointer is the FMU that is pointed by the MST. Further FIG. 4 illustrates a series of steps, the first of which is determining which FMU is the first non-erased (NER) FMU. As discussed above, prior to programming, a block is erased. After programming, the block becomes non-erased. The abort management module 112 is configured to analyze the different FMUs in the block in order to determine in which state the FMUs reside (one of which is non-erased). The second step is scanning forward from the NER FMU to determine the truly erased (TER) FMU, which is the FMU that is erased. Thereafter, scanning backward from NER FMU, the last stable FMU is determined. In this regard, the FMUs between the last stable FMU and the NER FMU are considered marginal, and the FMUs between the NER FMU and the TER FMU are considered under programmed.

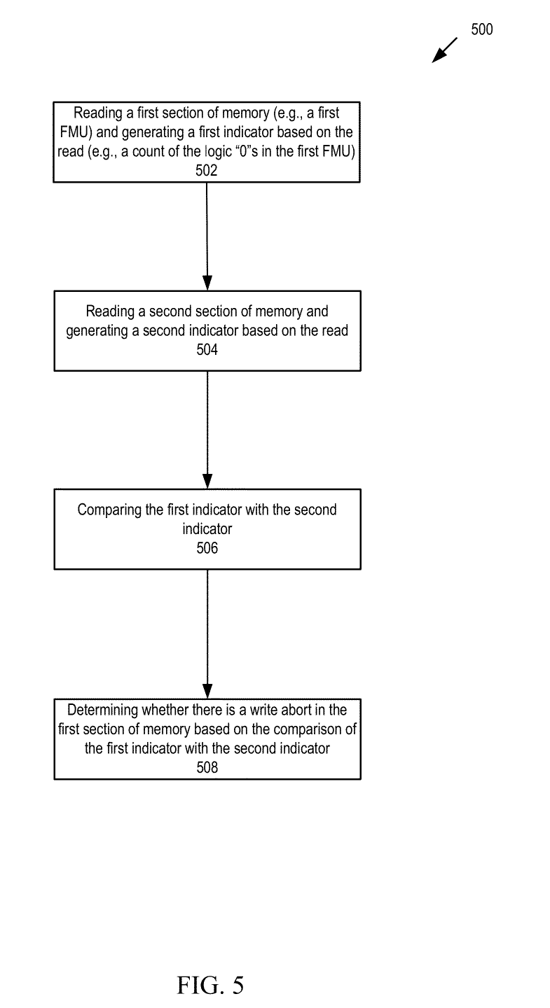

FIG. 5 is a first example of a flow diagram 500 to determine whether a write abort has occurred. At 502, a first section of memory is read in order to generate a first indicator based on the read. For example, a current FMU is read in order to count the number of logic “0”s in the current FMU. At 504, a second section of memory is read in order to generate a second indicator based on the read. At 506, the first indicator and the second indicator are compared. One example of the comparison is generated a difference or a differential between the first indicator and the second indicator. At 508, it is determined whether there is a write abort in the first section of memory based on the comparison of the first indicator with the second indicator. For example, the differential between the first and second indicators may be compared with a threshold to determine whether a write abort has occurred.

As discussed above, the detection method of write abort WLs may include reading the number of logic “0”s in a FMU in a WL (designated as “N”) in a suspected block after power-on. N may be used in multiple ways, including comparing N to one or more thresholds, and determining the differential of N with another FMU.

In a more specific embodiment, N may first be compared with one or more thresholds, and dependent on the comparison of N with the one or more thresholds, the differential of N with another FMU may be determined. For example, if N is between threshold₁ (which may be a value of 30) and threshold₂ (which may be a value of 60), the method includes reading the number of logic “0”s in a FMU in the last WL in the block, NL. Next, the method includes calculating the difference between the number of “0” in the WL FMU, N, and the number of logic “0” in the last WL FMU (designated as N_{L}) in the block. The method further includes marking the block as a write-abort block if the difference of logic “0”s, N-N_{L}, is above a differential truly-erased (TER) threshold pre-defined value. The differential TER threshold may be 5, however other differential TER threshold values like 10 or more may be determined and furthermore may be changed during the product life time.

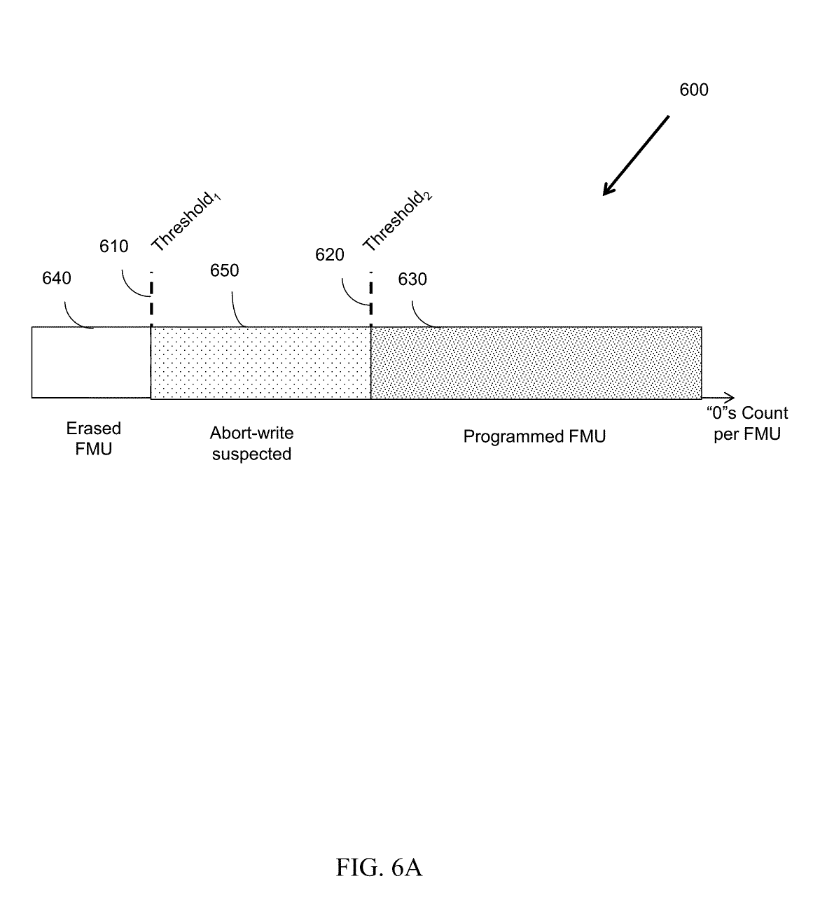

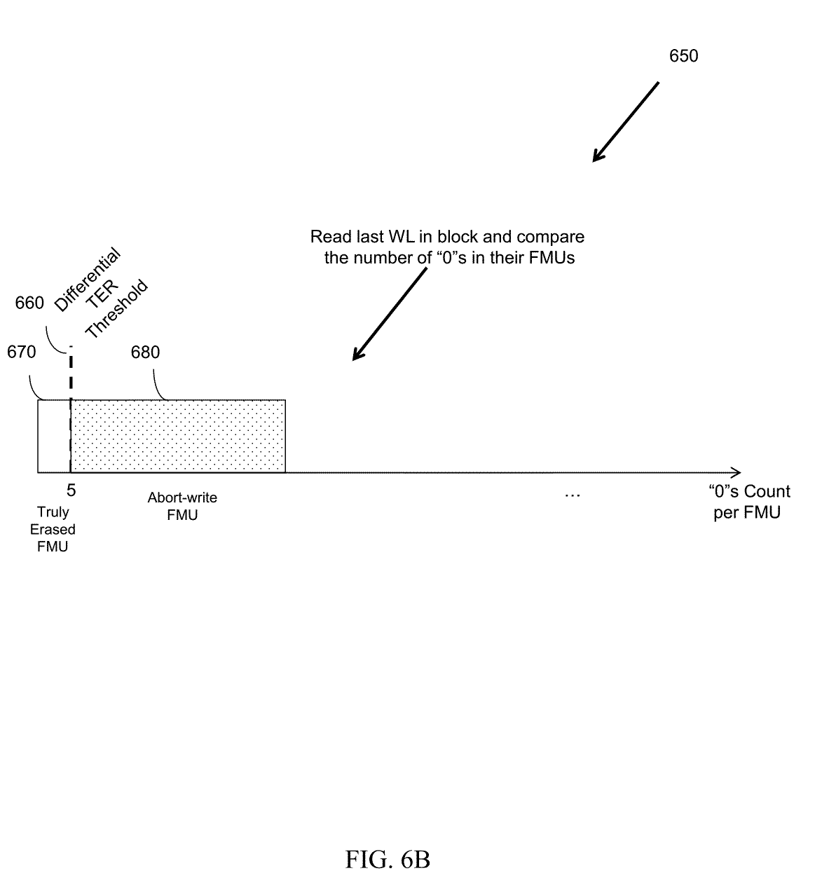

FIG. 6A illustrates a two threshold write abort detection scheme 600, with threshold₁ 610 and threshold₂ 620, that define three regions. Values of N that are greater than threshold₂ 620, designated as programmed FMU 630, are indicative of an FMU that is programmed. Values of N that are less than threshold₁ 610, designated as erased FMU 640, are indicative that the FMU is erased. Values of N that are in between threshold₁ 610 and threshold₂ 620, designated as abort-write suspected 650, are indicative that an abort-write is possible. For those FMU that are in abort-write suspected 650, differential analysis may be performed, such as illustrated in FIG. 6B.

FIG. 6B illustrates the write abort differential detection scheme that includes, in addition to the two thresholds illustrated in FIG. 6A, a third threshold, termed a differential TER threshold 660, which defines the allowed difference of erroneous programmed bits, “0”s count, between any WL FMU in a block and the last WL FMU in the block. As shown in FIG. 6B, differential TER threshold 660 has a value of 5. Accordingly, a marked write abort WL 680 includes a larger difference of erroneous programmed bits beyond the differential TER threshold 660, and WLs with lower differential values are deemed to be erased WLs. Thus, using the differential TER threshold 660 along with threshold₁ 610 and threshold₂ 620 may result in a more accurate assessment as to the write abort blocks, as opposed to only using threshold₁ 610 and threshold₂ 620.

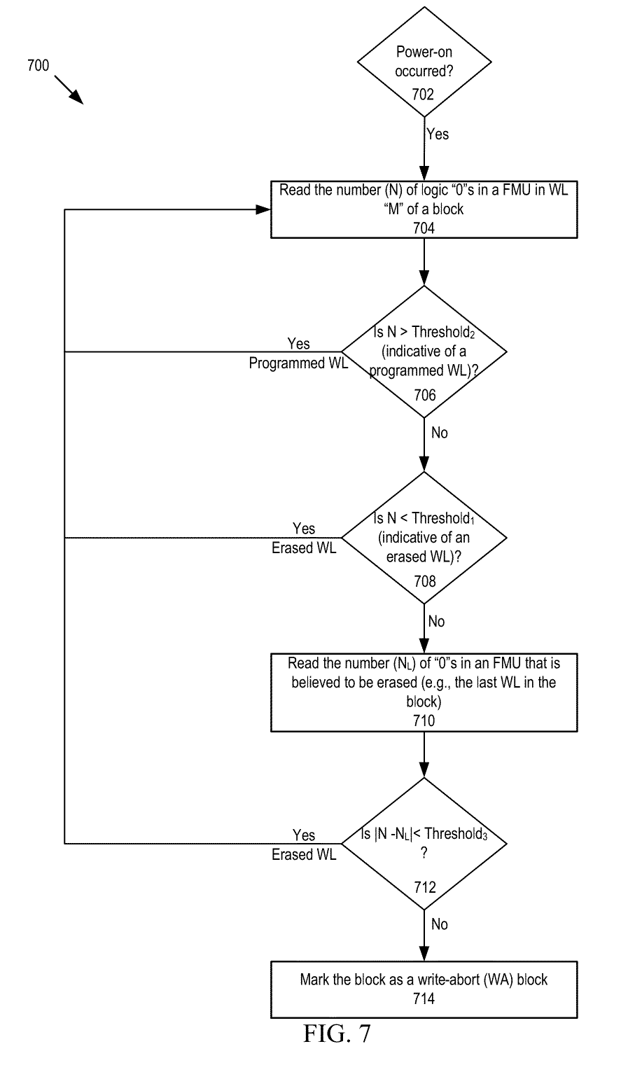

FIG. 7 is a second example of a flow diagram 700 to determine whether a write abort has occurred. At 702, it is determined whether a power-on has occurred. If so, at 704, the number of logic “0”s is read from an FMU in wordline “M”. Though FIG. 7 only focuses on analysis of a single wordline, multiple wordlines in a block may be analyzed. Typically, programming the WLs in a block occurs sequentially, WL after WL starting at WL 0, and ending with the last WL. Thus, the last WL will be the last to be programmed, and thus, the most likely WL in the block to remain erased. Further, the analysis may begin at WL 0 and step through the analysis of the wordlines in sequence.

At 706, it is determined if N is greater than threshold₂ (e.g., in programmed FMU 630 illustrated in FIG. 6A). If so, it is determined that the wordline is considered programmed. If not, at 708, it is determined if N is less than threshold₁ (e.g., in erased FMU 640 illustrated in FIG. 6A). If so, it is determined that the wordline is considered erased. If not, at 710, the number (N_{L}) of logic “0”s is read from a second FMU. The memory system may select the second FMU based on one or more qualities. For example, the memory system may select the second FMU from the last WL, which is most likely to be erased. At 712, the differential between N and N_{L} is compared to a third threshold. If the differential is less than the threshold, it is determined that the WL is erased. If not, at 714, the block in which the WL is contained is designated as a write-abort block.

Accordingly, the methods and systems discussed herein may be realized in hardware, software, or a combination of hardware and software. The method and system may be realized in a centralized fashion in at least one electronic device (such as illustrated in memory system 100 in FIG. 1A) or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein. Such a programmed computer may be considered a special-purpose computer.

The method and system may also be implemented using a computer-readable media. For example, abort management module 112 may be implemented using computer-readable media to implement the functionality described herein, such as discussed in FIGS. 5-7. A “computer-readable medium,” “computer-readable storage medium,” “machine readable medium,” “propagated-signal medium,” or “signal-bearing medium” may include any tangible device that has, stores, communicates, propagates, or transports software for use by or in connection with an instruction executable system, apparatus, or device. The machine-readable medium may selectively be, but not limited to, an electronic, magnetic, optical, electromagnetic, infrared, or semiconductor system, apparatus, device, or propagation medium. The computer-readable medium can be a single medium or multiple media. Accordingly, the disclosure may be considered to include any one or more of a computer-readable medium or a distribution medium and other equivalents and successor media, in which data or instructions can be stored. As another example, the flash memory interface(s) may be configured to implement the functionality described herein. In either example, the system controller 102 may include a device that is configured to perform the functionality described herein.

Alternatively or in addition, dedicated hardware implementations, such as application specific integrated circuits, programmable logic arrays and other hardware devices, may be constructed to implement one or more of the methods described herein. Applications that may include the apparatus and systems of various embodiments may broadly include a variety of electronic and computer systems. One or more embodiments described herein may implement functions using two or more specific interconnected hardware modules or devices with related control and data signals that may be communicated between and through the modules, or as portions of an application-specific integrated circuit. Accordingly, the present system may encompass software, firmware, and hardware implementations.

The above-disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present embodiments are to be determined by the broadest permissible interpretation of the following claims and their equivalents, and shall not be restricted or limited by the foregoing detailed description. While various embodiments have been described, it will be apparent to those of ordinary skill in the art that many more embodiments and implementations are possible within the scope of the above detailed description. Accordingly, the embodiments are not to be restricted except in light of the attached claims and their equivalents.

What is claimed is:

1. A memory system comprising:
a differential generator module configured to generate a differential between an aspect in data values stored a first section in memory and the aspect in data values stored a second section in memory;
a comparison module configured to compare the differential with a differential threshold; and
a write abort module configured to determine, based on the comparison of the differential with the differential threshold, whether at least one of the first section or the second section is subject to a write abort.

2. The memory system of claim 1, wherein the aspect comprises a count of a predetermined value in the data values stored in a respective section in memory.

3. The memory system of claim 2, wherein the predetermined value comprises an erase value.

4. The memory system of claim 2, wherein the predetermined value comprises a logic “0” value.

5. The memory system of claim 1, wherein the first section of memory is in a respective block; and
wherein the second section of memory is in the same respective block.

6. The memory system of claim 5, wherein the respective block comprises a plurality of wordlines; and
wherein the first section of memory comprises a first wordline in the same respective block;
wherein the second section of memory comprises a second wordline in the same respective block; and
wherein the first wordline is different from the second wordline.

7. The memory system of claim 6, wherein the second section of memory is in a last wordline of a programming sequence for the respective block.

8. The memory system of claim 6, wherein the aspect comprises a first count of a predetermined value in the data values stored in the first section of memory and a second count of the predetermined value in the data values stored in the first section of memory; and
wherein the differential generator module is configured to generate a difference between the first count and the second count.

9. The memory system of claim 8, wherein the first section of memory and the second section of memory include common column errors; and
wherein the differential generator module, by generating the difference between the first count and the second count, is configured to reduce an effect of the common column errors on determining whether the write abort has occurred.

10. The memory system of claim 1, further comprising a second comparison module configured to compare the aspect of the first section of memory with one or both of an erased threshold and a programmed threshold;
wherein, in response to determining that the aspect of the first section of memory is in between the erased threshold and the programmed threshold, triggering execution of the differential generator module.

11. The memory system of claim 10, wherein, in response to the second comparison module determining that the aspect of the first section of memory is less than the erased threshold, the write abort module is further configured to determine that the first section of memory is erased; and
wherein, in response to the second comparison module determining that the aspect of the first section of memory is greater than the programmed threshold, the write abort module is further configured to determine that the first section of memory is programmed.

12. A method for determining whether a write abort occurred when writing to a section of memory, the method comprising:
reading a first part of the section of the memory in order to generate a first count;
reading a second part of the memory in order to generate a second count;
comparing the first count with the second count; and
determining, based on the comparison of the first count with the second count, whether a write abort occurred at the first section of the memory.

13. The method of claim 12, wherein the section of the memory comprises a block; and
wherein the second part of the memory is in a same block as the first section of memory, the second part being in a different part of the same block than the first part.

14. The method of claim 13, wherein the second part of the block is in a last wordline of the block.

15. The method of claim 13, wherein comparing the first count with the second count comprises generating a differential between the first count and the second count.

16. The method of claim 15, wherein determining whether the write abort occurred at the first section of the memory comprises:
determining whether the differential is greater than a differential threshold; and
in response to determining that the differential is greater than the differential threshold, determining that the write abort occurred in the first section of memory.

17. The method of claim 15, wherein reading the first part of the section of the memory to generate the first count comprises counting logic “0”s in the first part of the section of the memory.

18. The method of claim 17, further comprising comparing the first count with one or more thresholds; and
in response to the comparison, triggering the generating of the differential between the first count and the second count.

19. The method of claim 18, wherein comparing the first count with one or more thresholds comprises comparing the first count to one or both of an erased threshold and a programmed threshold; and
wherein generating the differential between the first count and the second count is triggered in response to determining that the first count is in between the erased threshold and the programmed threshold.

20. The method of claim 19, further comprising:
in response to determining that the first count is less than the erased threshold, designating the first section of memory as being erased; and
in response to determining that the first count is greater than the programmed threshold, designating the first section of memory as being programmed.

21. The method of claim 12, wherein the first part of the section of memory and the second part of the section of memory include common errors;
wherein comparing the first count with the second count comprises generating a difference between the first count and the second count; and
wherein the difference reduces an effect of the common errors in the first part and the second part.

22. The method of claim 21, wherein the first part of the section of memory and the second part of the section of memory are in a same block of memory;
wherein the first part of the section of memory comprises a first wordline in the same block of memory;
wherein the second part of the section of memory comprises a second wordline in the same block of memory; and
wherein the first wordline is different from the second wordline.
